(19) United States
(12) Patent Application Publication
(10) Pub. No.: US 2025/0343115 A1
(43) Pub. Date: Nov. 6, 2025

(54) SEMICONDUCTOR DEVICE INCLUDING INSULATING STRUCTURE SURROUNDING THROUGH VIA AND METHOD FOR FORMING THE SAME

(71) Applicant: Taiwan Semiconductor Manufacturing Company, Ltd., Hsinchu (TW)

(72) Inventors: Harry-Haklay Chuang, Zhubei City (TW); Shiang-Hung Huang, New Taipei City (TW); Hsin Fu Lin, Hsinchu County (TW)

(21) Appl. No.: 19/271,873

(22) Filed: Jul. 17, 2025

Related U.S. Application Data
(63) Continuation of application No. 18/155,912, filed on Jan. 18, 2023.
(60) Provisional application No. 63/408,196, filed on Sep. 20, 2022.

(51) Int. Cl. H01L 23/48; H01L 21/762; H01L 21/768; H01L 23/522

(52) U.S. Cl. CPC H01L 23/481; H01L 21/76224; H01L 21/76898; H01L 23/5226

(57) ABSTRACT

The present disclosure provides a semiconductor device. The semiconductor device includes: a substrate having a device area and a peripheral area surrounding the device area; a via, disposed at the peripheral area and extending at least partially through the substrate; an insulating structure, disposed at the peripheral area, extending at least partially through the substrate and surrounding the via; and a doped region, disposed at the peripheral area, over or in the substrate and adjacent to the via.

### REFERENCE TO RELATED APPLICATIONS

This Application is a Continuation of U.S. application Ser. No. 18/155,912, filed on Jan. 18, 2023, which claims the benefit of U.S. Provisional Application No. 63/408,196, filed on Sep. 20, 2022. The contents of the above-referenced Patent Applications are hereby incorporated by reference in their entirety.

### BACKGROUND

When a semiconductor device, such as a metal-oxide-semiconductor field-effect transistor (MOSFET), is scaled down through various technology nodes, many challenges may appear during the implementation of features and processes in complementary metal-oxide-semiconductor (CMOS) fabrication. As the gate length and spacing between devices decrease, the above-mentioned problems are exacerbated. For example, it is difficult to prevent parasitic capacitance among gate stacks of the MOSFET because of the reduced spacing between the gate stacks, thereby affecting the device performance.

### BRIEF DESCRIPTION OF THE DRAWINGS

Aspects of embodiments of the present disclosure are best understood from the following detailed description when read with the accompanying figures. It should be noted that, in accordance with standard practice in the industry, various structures are not drawn to scale. In fact, dimensions of the various structures can be arbitrarily increased or reduced for clarity of discussion.

FIG. 1 is a schematic cross-sectional view of a semiconductor device, in accordance with some embodiments of the present disclosure.

FIG. 2 is a schematic top view showing a portion of the semiconductor device in FIG. 1, in accordance with some embodiments of the present disclosure.

FIG. 3 is a flow diagram showing a method of fabricating a semiconductor device, in accordance with some embodiments of the present disclosure.

FIGS. 4 to 29 are schematic cross-sectional views illustrating sequential operations of the method shown in FIG. 3, in accordance with some embodiments of the present disclosure.

FIGS. 30A, 30B, 31A and 31B are schematic top views showing portions of the semiconductor device in FIG. 1, in accordance with various embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features can be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages, such as those for quantities of materials, durations of times, temperatures, operating conditions, ratios of amounts, and the likes thereof disclosed herein, should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

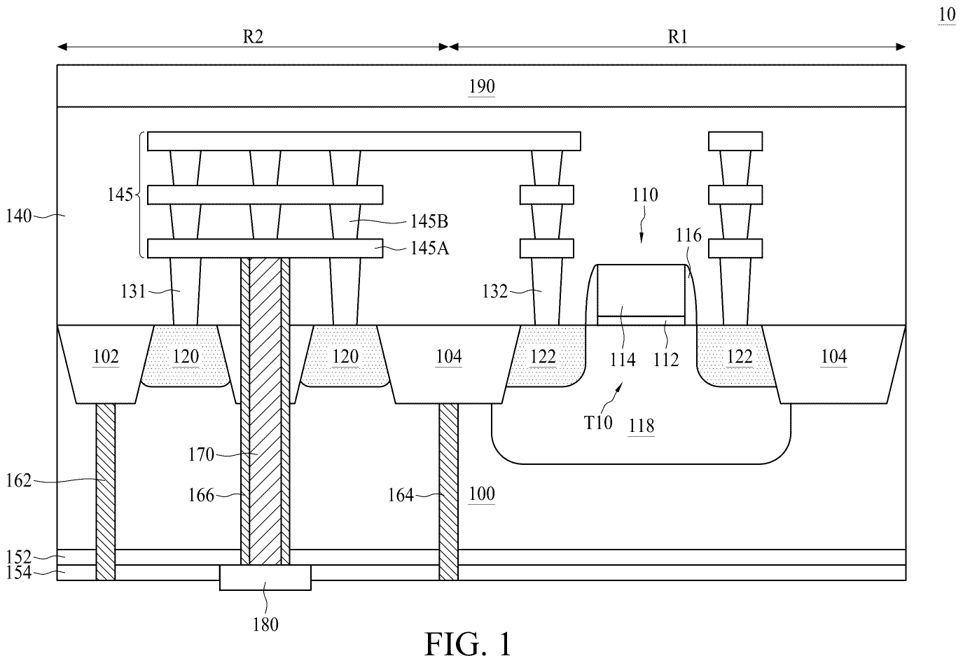

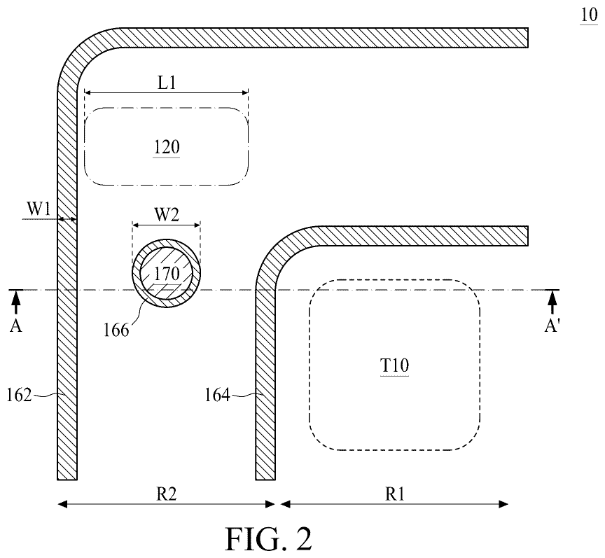

FIG. 1 is a schematic cross-sectional view of a semiconductor device 10. FIG. 2 is a schematic top view of the semiconductor device 10 in FIG. 1. The cross-sectional view of FIG. 1 is along line A-A′ of FIG. 2. Referring to FIG. 1, the semiconductor device 10 includes a substrate 100 that is defined with a device area R1 and a peripheral area R2 adjacent to or surrounding the device area R1. Multiple isolation structures 102, 104 are disposed in the substrate 100. Multiple doped regions 120, 122 are disposed in the substrate 100 and separated by the isolation structures 102, 104. The doped regions 122 are disposed in the device area R1, and the doped regions 120 are disposed in the peripheral area R2. In some embodiments, the doped regions 120, 122 may have the same doping type (e.g., P type) as the substrate 100. A well 118 (e.g., an N well) is disposed between two isolation structures 104, in the device area R1 and within the substrate 100. In some embodiments, the well 118 may have a different doping type (e.g., N type) from the substrate 100. The doped regions 122 are disposed in the well 118. A transistor T10 is disposed over the well 118. The transistor T10 includes a gate structure 110 and the doped regions 122. The gate structure 110 includes a gate dielectric layer 112, a gate electrode layer 114 and a gate spacer 116. The gate dielectric layer 112 is disposed on the substrate 100 between two isolation structures 104. The gate electrode layer 114 is disposed on the gate dielectric layer 112. The gate spacer 116 surrounds the gate electrode layer 114 and the gate dielectric layer 112.

An inter-layer dielectric (ILD) layer 140 is disposed on the substrate 100 and over the transistor T10. Multiple conductive contacts 131, 132 and an interconnect structure 145 electrically coupled to the conductive contacts 131, 132 are embedded in the ILD layer 140. The interconnect structure 145 includes multiple higher-level conductive features such as conductive lines 145A and conductive vias 145B. One end of the interconnect structure 145 is electrically coupled to the doped region 120, and another end of the interconnect structure 145 is electrically coupled to the doped regions 122 and the transistor T10.

A through-silicon via (TSV) structure 170 is disposed in the peripheral area R2. The TSV structure 170 extends at least partially through the substrate 100 and/or the ILD layer 140. In some embodiments, the TSV structure 170 is surrounded by a first insulating feature 166. The TSV structure 170 is isolated from the substrate 100 by the first insulating feature 166. In some embodiments, the TSV structure 170 directly contacts the first insulating feature 166. Multiple second insulating features 162, 164 are disposed in the peripheral area R2. In some embodiments, the second insulating features 162 and 164 extend parallel to each other. In some embodiments, each of the second insulating features 162, 164 is parallel to the first insulating feature 166. The second insulating features 162, 164 extend at least partially through the substrate 100 and surround the TSV structure 170. The TSV structure 170 is separated from the second insulating features 162, 164. The interconnect structure 145 is disposed over the TSV structure 170 and the second insulating features 162, 164. The interconnect structure 145 is electrically coupled to the TSV structure 170 through the conductive line 145A. A first passivation layer 152 (for example, made of silicon oxide) is disposed on one side of the substrate 100 facing away from the interconnect structure 145. A second passivation layer 154 (for example, made of silicon nitride) is disposed on the first passivation layer 152. A conductive pad 180 is disposed on and electrically coupled to the TSV structure 170. A bias voltage may be applied to the TSV structure 170 via the conductive pad 180.

Referring to FIG. 2, from the top view of the semiconductor device 10, the second insulating feature 164 is disposed at one side of the TSV structure 170, and the second insulating feature 162 is disposed at another side of the TSV structure 170. The second insulating feature 164 is closer to the device area R1 than the second insulating feature 162. In some embodiments, the second insulating feature 164 is a ring structure that surrounds the device area R1, and FIG. 2 only shows a portion of the second insulating feature 164. The second insulating feature 164 separates the TSV structure 170 in the peripheral area R2 from the transistor T10 in the device area R1. In some embodiments, the second insulating feature 162 is a ring structure that encloses the doped region 120 and the TSV structure 170 with the second insulating feature 164, and FIG. 2 only shows a portion of the second insulating feature 162. The doped region 120 is disposed adjacent to the TSV structure 170 and between the second insulating feature 162 and the second insulating feature 164. Each of the second insulating features 162 and 164 has a width W1 between about 0.3 micrometers (μm) and about 5 μm, approximately 0.8 μm, or other similar values. The TSV structure 170 and the first insulating feature 166 together have a width W2 between about 1 μm and about 10 μm, between about 3 μm and about 4 μm, or other similar values. The doped region 120 has a length L1 between about 0.1 μm and about 10 μm, approximately 2 μm, or other similar values.

Without coupling the interconnect structure 145 to a part of the substrate 100 between the second isolating features, a high voltage applied to the TSV structure 170 could lead to dielectric breakdown of the first insulating feature 166 (e.g., since neighboring parts of the substrate 100 are substantially grounded). However, because the interconnect structure 145 couples the TSV structure 170 to the doped region 120, a part of the substrate 100 that is between the second insulating features 162, 164 can be held at a substantially same voltage potential as the TSV structure 170. Holding the TSV structure 170 and the part of the substrate 100 that is between the second insulating features 162, 164 at the substantially same voltage potential mitigates an electric field between the TSV structure 170 and the substrate 100 and thereby reduces dielectric breakdown between the TSV structure 170 and the substrate 100 during an application of high voltages (e voltages greater than or equal to approximately 200 V). Therefore, the disclosed structure may be used in high-voltage applications. Furthermore, the second insulating features 164 will mitigate any diffusion of metal (e.g., copper) from the TSV structure 170 to the device area R1.

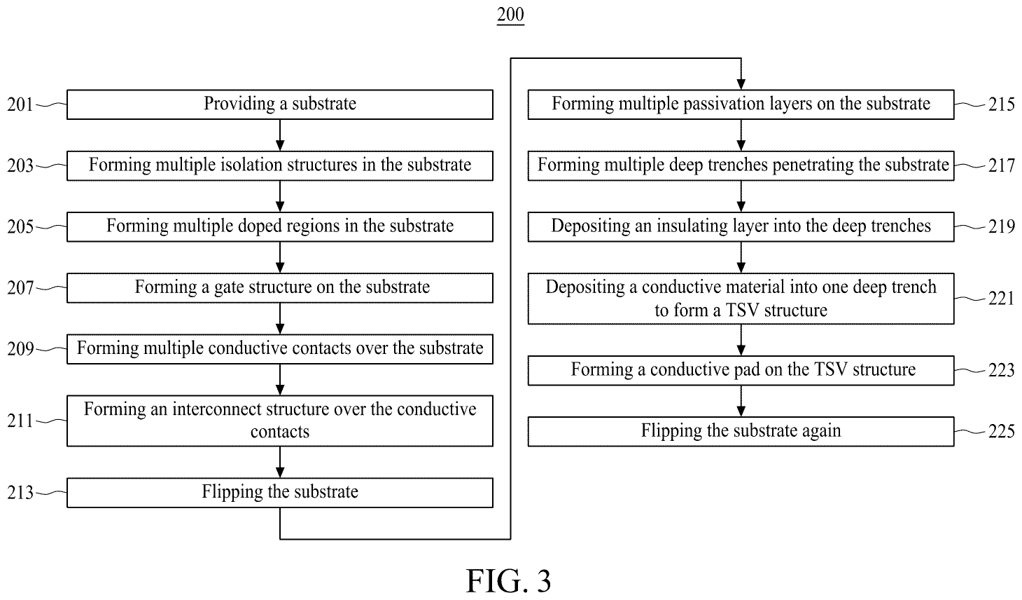

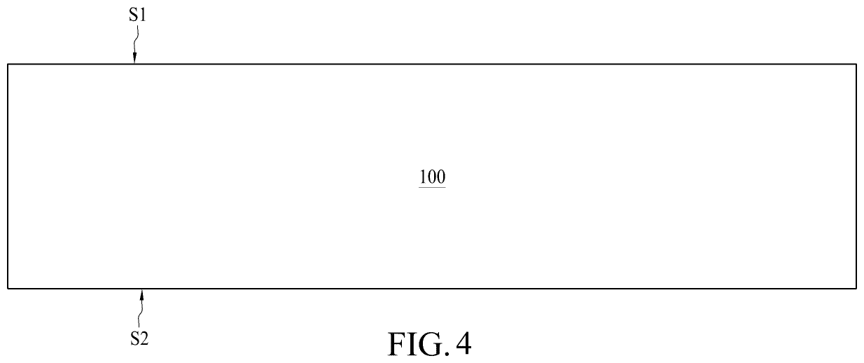

FIG. 3 is a flow diagram showing a method 200 of fabricating the semiconductor device 10 in FIG. 1. FIGS. 4 to 29 are schematic cross-sectional views illustrating sequential operations of the method 200 shown in FIG. 3. The method 200 includes a number of operations (201, 203, 205, 207, 209, 211, 213, 215, 217, 219, 221, 223 and 225) and the description and illustration are not deemed as a limitation to the sequence of the operations.

In operation 201 of FIG. 3, a substrate 100 is provided, as shown in FIG. 4. The substrate 100 may be a semiconductor substrate such as a bulk silicon wafer. In some embodiments, the substrate 100 is a semiconductor-on-insulator (SOI) substrate, a multi-layered or gradient substrate, or the like. The substrate 100 may include a semiconductor material such as Si; Ge; a compound or alloy semiconductor including SiC, SiGe, GaAs, GaP, GaAsP, AlInAs, AlGaAs, GaInAs, InAs, GaInP, InP, InSb or GaInAsP; or a combination thereof. The substrate 100 may be doped or undoped. In some embodiments, the substrate 100 includes P-type single crystalline silicon. The substrate has a first surface S1 and a second surface S2 opposite to the first surface S1.

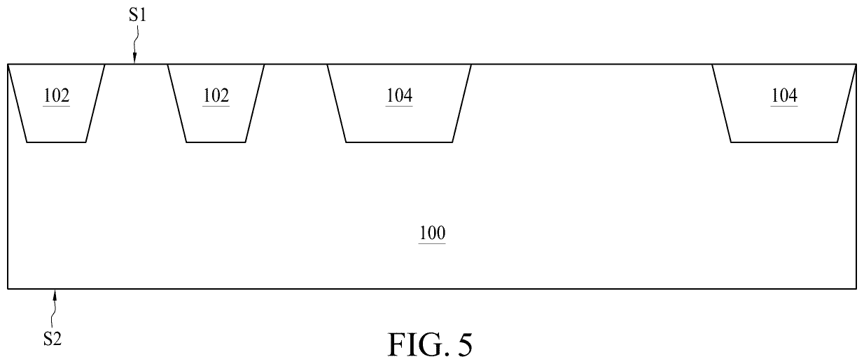

In operation 203 of FIG. 3, multiple isolation structures 102, 104 are formed in the substrate 100, as shown in FIG. 5. The isolation structures 102, 104 may be shallow trench isolation (STI) regions in the substrate 100. In some other embodiments, the isolation structures 102, 104 are formed over the substrate 100. The STI regions may have different widths or sizes. For example, the isolation structures 104 have a size greater than that of the isolation structures 102. The formation of the isolation structures 102, 104 includes forming multiple trenches on the first surface S1 in the substrate 100 by any acceptable etching operation, such as reactive ion etching (RIE) or dry etching. An insulating material is then deposited to fill the trenches. The insulating material may be silicon oxide, silicon nitride, or a combination thereof. The insulating material may be deposited using chemical vapor deposition (CVD), atmospheric pressure CVD (APCVD), high-density plasma CVD (HDP-CVD), or another suitable method. A planarization operation, such as a chemical mechanical polishing (CMP) operation, is used to remove any excess insulating material from the first surface S1 such that top surfaces of the isolation structures 102, 104 are coplanar with the first surface S1 (e.g., coplanar within a tolerance of the CMP operation).

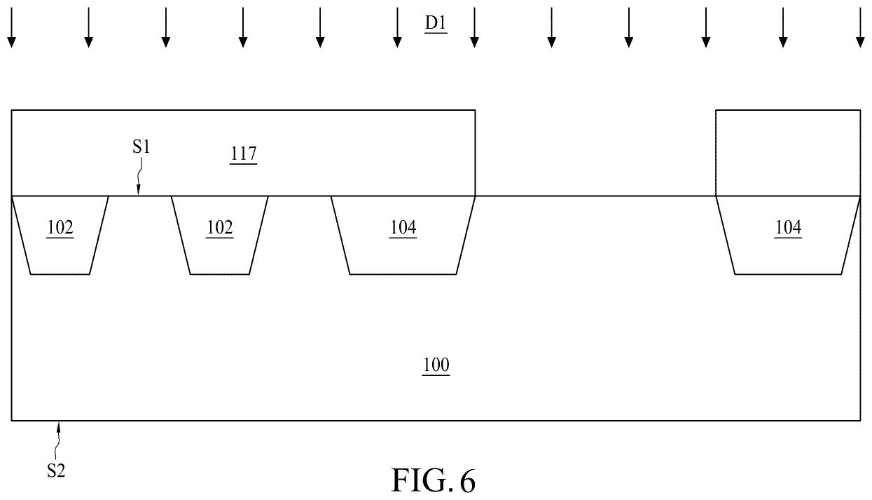

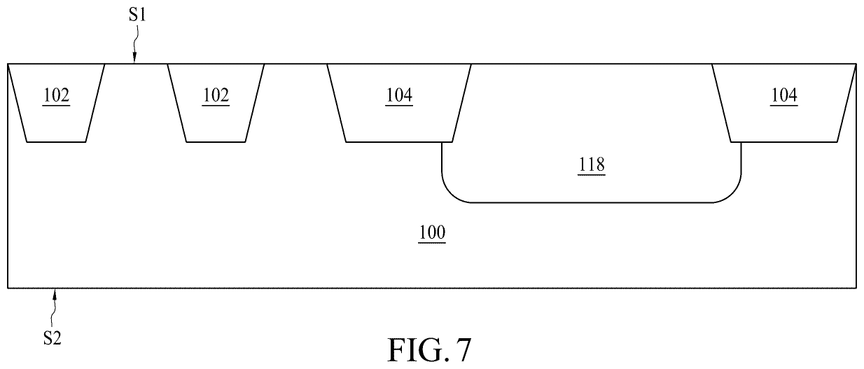

In operation 205 of FIG. 3, multiple doped regions are formed in the substrate 100, as shown in FIGS. 6 and 7. Referring to FIG. 6, an implant mask 117 is formed on portions of the substrate 100 while a portion of the substrate 100 between the isolation structures 104 is exposed. A first ion-implantation operation D1 is performed on the exposed substrate 100. The first ion-implantation operation D1 may employ dopants having a first doping type. In some embodiments, the dopants may comprise N-type dopants such as phosphorus (P) or arsenic (As) atoms or ions. The opening of the implant mask 117 allows the dopants to penetrate into the substrate 100. After an amount of time, depending on a desired depth of a well, the first ion-implantation operation D1 is stopped.

Referring to FIG. 7, the N-type dopants may diffuse to a predetermined depth in the substrate 100, and a well 118 is formed. The well 118 is formed at the first surface S1 and between the isolation structures 104. The implant mask 117 is then removed. An annealing operation, such as a rapid thermal annealing (RTA) operation, may be used to activate the implanted dopants. In some embodiments, the well 118 may comprise an N well configured to act as a conductive region and used as a body for a P-channel transistor. Although not specifically illustrated, appropriate doped regions may be formed in the substrate 100. For example, lightly-doped drain (LDD) regions may be formed in the well 118 after the formation of the well 118. In some other examples, the LDD regions may be formed after the operation 205.

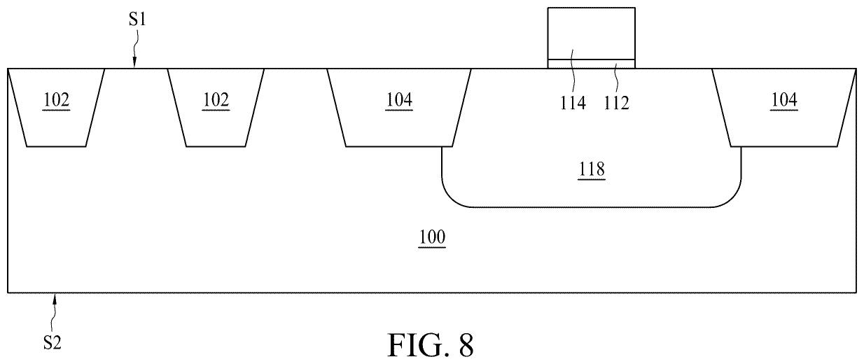

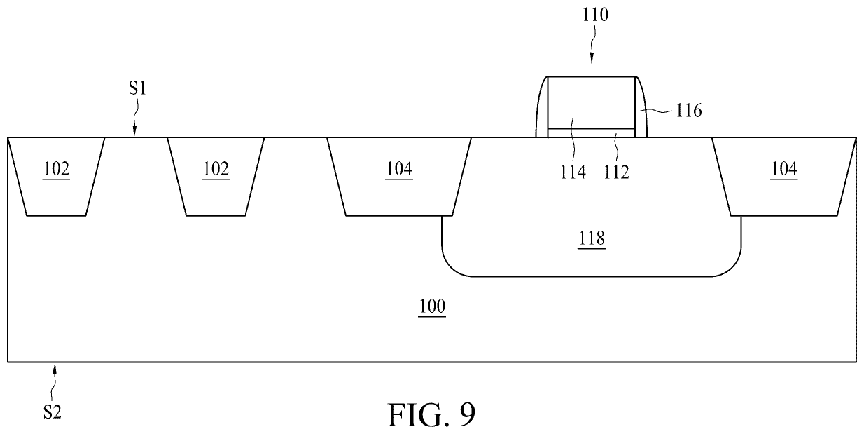

In operation 207 of FIG. 3, a gate structure 110 is formed on the substrate 100, as shown in FIGS. 8 and 9. Referring to FIG. 8, in some embodiments, the formation of the gate structure 110 includes depositing or thermally growing an oxide layer on the first surface S1 of the substrate 100. A polysilicon layer may then be formed on the oxide layer using CVD or other suitable methods. A photoresist pattern or a patterned nitride hardmask is formed on the polysilicon layer. An etching operation, such as RIE or dry etching, is used to pattern the polysilicon layer and the oxide layer. A pattern of the photoresist pattern or the patterned nitride hardmask is transferred to the polysilicon layer and the oxide layer to form a gate electrode layer 114 and a gate dielectric layer 112, respectively. The gate dielectric layer 112 is formed on the first surface S1 between the isolation structures 104, and the gate electrode layer 114 is formed on the gate dielectric layer 112.

Referring to FIG. 9, a gate spacer 116 may be formed surrounding the gate electrode layer 114 and the gate dielectric layer 112. The formation of the gate spacer 116 includes conformally forming a dielectric material on the substrate 100, the isolation structures 102, 104, the gate dielectric layer 112 and the gate electrode layer 114 using CVD or other suitable methods. The dielectric material may be silicon nitride, silicon carbon nitride, a combination thereof, or the like. An anisotropic etching operation is used to remove portions of the dielectric material and leave the dielectric material on sidewalls of the gate dielectric layer 112 and the gate electrode layer 114, thereby forming the gate spacer 116. The gate dielectric layer 112, the gate electrode layer 114 and the gate spacer 116 form the gate structure 110. The order of formations of the gate structure 110 and the well 118 may not be limited. In some other embodiments, the formation of the gate structure 110 is prior to the formation of the well 118.

Although not specifically illustrated, in some other embodiments, the gate structure 110 is formed using a “replacement metal gate (RMG)” technique. For example, a dummy gate structure may be formed on the first surface S1 of the substrate 100. The dummy gate structure includes a dummy gate dielectric layer and a dummy gate electrode layer on the dummy gate dielectric layer. The dummy gate structure may be replaced by a functional gate structure. The functional gate structure may include a high-dielectric constant (high-k) dielectric material as its gate dielectric layer and one or more metals as its gate electrode layer. The high-k dielectric material may include HfO₂, HfSiO, HfSION, HfTaO, HfTIO, HfZrO or other suitable dielectric materials. The metal may include W, Cu, Co, Al, Ni, Ta, Ti, Mo, Pd, Pt, Ru, Ir, Ag, Au, the like, or a combination thereof. A diffusion-blocking layer and/or a work function layer may be disposed between the gate dielectric layer and the gate electrode layer. The diffusion-blocking layer and the work function layer may include TIN, TaN, WN, the like, or a combination thereof.

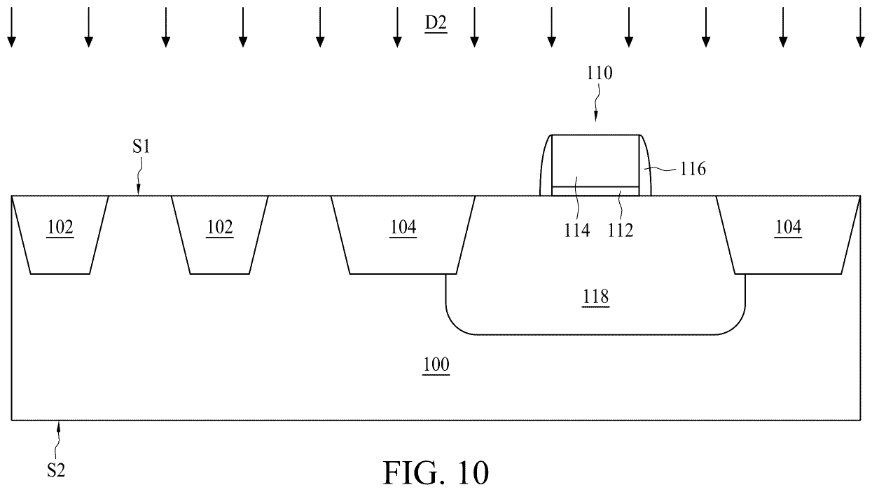

Referring to FIG. 10, a second ion-implantation operation D2 is performed on the exposed substrate 100. The second ion-implantation operation D2 may employ dopants having a second doping type. In some embodiments, the dopants may comprise P-type dopants such as boron (B), indium (In) or gallium (Ga) atoms or ions. The gate spacer 116 may function as an implant mask during the second ion-implantation operation D2. After an amount of time, depending on a desired depth of a doped region, the second ion-implantation operation D2 is stopped.

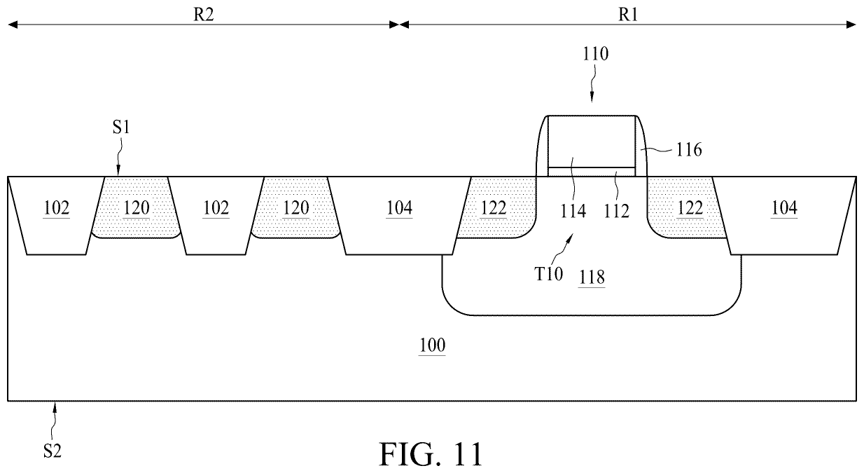

Referring to FIG. 11, the dopants may diffuse to a predetermined depth in the substrate 100, and multiple doped regions 120, 122 are formed. The doped regions 120, 122 are formed at the first surface S1 and between the isolation structures 102, 104. An annealing operation, such as an RTA operation, may be used to activate the implanted dopants. In some embodiments, wherein the doped regions 120, 122 are P-type and conductive, the doped region 120 may be referred to as a P⁺ oxide definition (OD) region, and its function will be described below. The doped regions 122 are within the well 118 and at opposite sides of the gate structure 110. After the formation of the doped regions 122, a transistor T10 is formed. The transistor T10 includes the gate structure 110 serving as a gate terminal and the doped regions 122 serving as source/drain (S/D) terminals. The substrate 100 may be defined with a device area R1 and a peripheral area R2 adjacent to the device area R1. The device area R1 is a region where the transistor T10 or other transistors are disposed. The peripheral area R2 is a region where no transistor is disposed. The peripheral area R2 may surround the device area R1.

Although not specifically illustrated, appropriate doped regions may be formed in the substrate 100. For example, LDD regions may be formed in the well 118 after the formation of the gate spacer 116 or before the formation of the doped regions 120, 122. Due to a presence of the LDD regions, the transistor T10 has a smaller electric field near the drain region and therefore a so-called hot-carrier effect can be reduced.

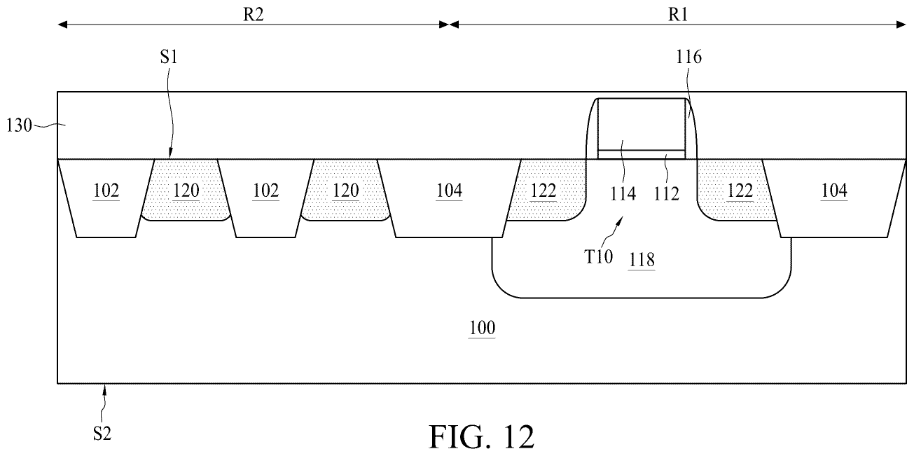

In operation 209 of FIG. 3, multiple conductive contacts 131, 132 are formed over the substrate 100, as shown in FIGS. 12 to 14. Referring to FIG. 12, an inter-layer dielectric (ILD) layer 130 is formed over the substrate 100. The ILD layer 130 may be formed using spin-on coating, CVD, ALD, and/or other suitable methods. The ILD layer 130 may be made of silicon oxide, silicon nitride, undoped silicate glass (USG), phospho-silicate glass (PSG), boro-silicate glass (BSG), boron-doped phospho-silicate glass (BPSG), tetraethyl orthosilicate (TEOS), or other suitable materials. In some embodiments, the dielectric material of the ILD layer 130 includes an extreme low-k (ELK) dielectric material, which has a dielectric constant between 2.0 and 3.0. The ILD layer 130 may cover the isolation structures 102, 104, the doped regions 120, 122 and the transistor T10. In some embodiments, a CMP operation is used to planarize the ILD layer 130 without exposing a top surface of the transistor T10. In such embodiments, a top surface of the planarized ILD layer 130 is higher than the top surface of the transistor T10, as shown in FIG. 12.

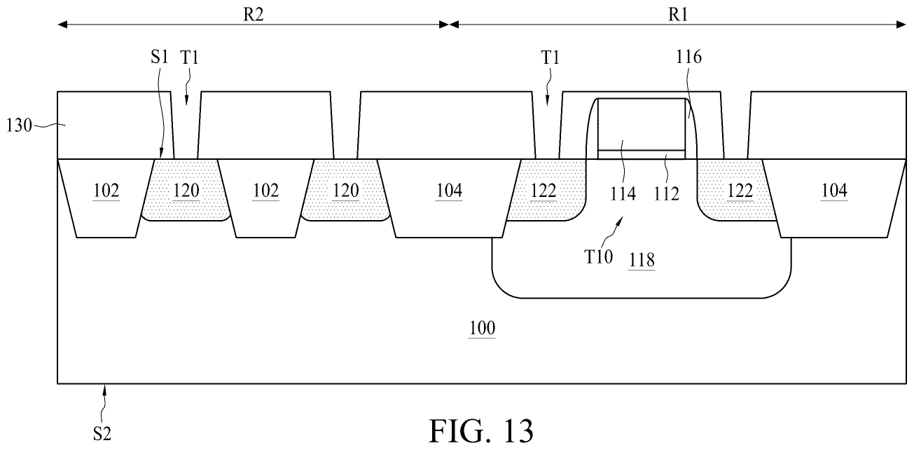

Referring to FIG. 13, multiple contact holes T1, T2 are formed in the ILD layer 130. The contact holes T1, T2 may be formed using any acceptable etching operation, such as RIE or dry etching. The contact holes T1, T2 may penetrate the ILD layer 130. The contact hole T1 may expose the doped region 120, and the contact hole T2 may expose the doped region 122.

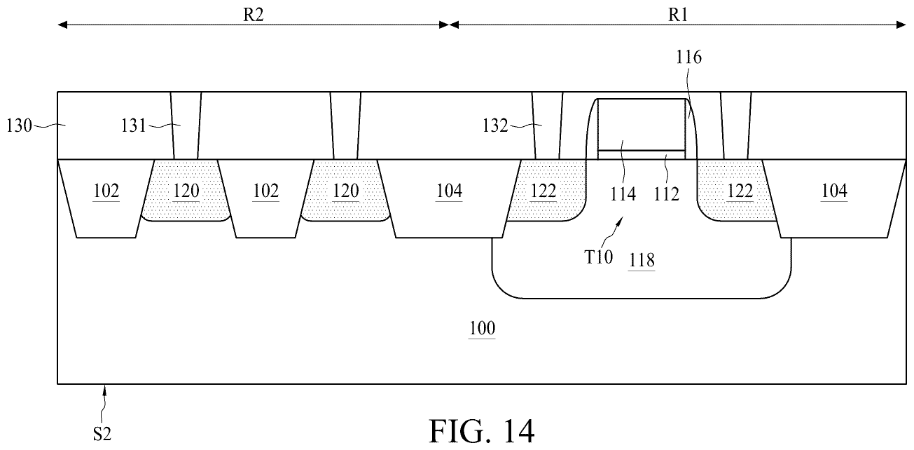

Referring to FIG. 14, a conductive material, such as W, Cu, Co, Al, Ni, Ta, Ti, Mo, Pd, Pt, Ru, Ir, Ag, Au, the like, or a combination thereof, is deposited in the contact holes T1, T2. The conductive material may be formed using sputtering, electroplating, PVD, or other suitable methods. A CMP operation is used to remove any excess conductive material from the top surface of the ILD layer 130, thereby forming the conductive contacts 131, 132. The conductive contacts 131, 132 may be formed simultaneously or separately, and the order for forming the conductive contacts 131 and 132 is not limited. The conductive contact 131 may be electrically coupled to the doped region 120, and the conductive contact 132 may be electrically coupled to the doped region 122. Although not specifically illustrated, a diffusion barrier layer (not shown) may be disposed between each of the conductive contacts 131 and the ILD layer 130 and between each of the conductive contacts 132 and the ILD layer 130. The diffusion barrier layer may be formed of TIN, TaN, Ta, Ti, TiSN, TaSN, W, WN, or combinations thereof, using ALD, PVD or other suitable methods. The diffusion barrier layer may be used to prevent the conductive material of the conductive contacts 131, 132 from diffusing into the ILD layer 130.

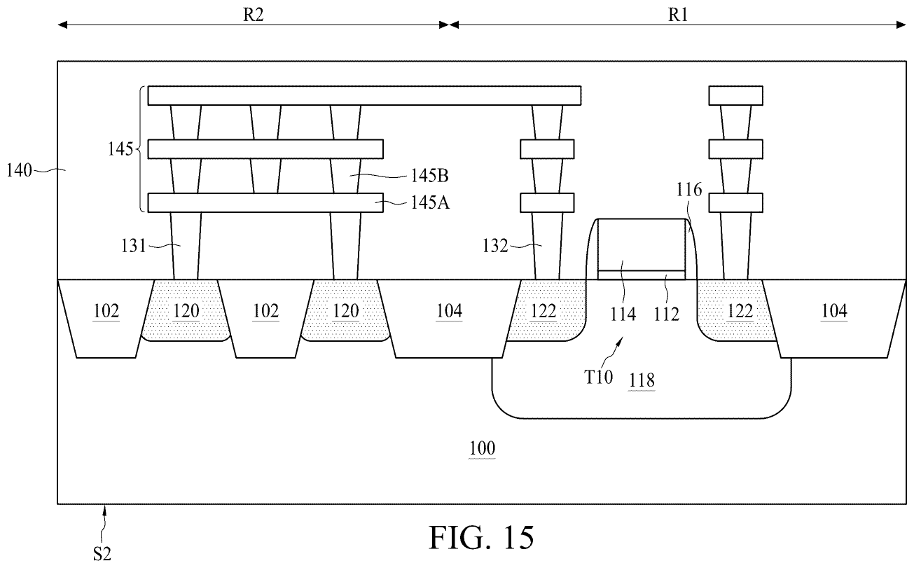

In operation 211 of FIG. 3, an interconnect structure 145 is formed over the conductive contacts 131, 132, as shown in FIG. 15. The interconnect structure 145 includes multiple higher-level conductive features such as conductive lines 145A and conductive vias 145B. Prior to the formation of the interconnect structure 145, more dielectric materials may be formed over the ILD layer 130 to form an ILD layer 140. The ILD layer 140 may be formed by repeatedly stacking dielectric materials as each layer of conductive lines or conductive vias is formed. Although not illustrated, the interconnect structure 145 may be formed using a series of lithographic, etching, deposition and planarization operations. The conductive lines and the conductive vias may be formed using a single-damascene method or a dual-damascene method. The conductive lines and the conductive vias may be embedded in one or more dielectric layers. The interconnect structure 145 is surrounded by the ILD layer 140. The conductive lines and the conductive vias may be electrically coupled to each other. The interconnect structure 145 may be electrically coupled to the conductive contacts 131, 132, the doped regions 120, 122 and the transistor T10 or more transistors.

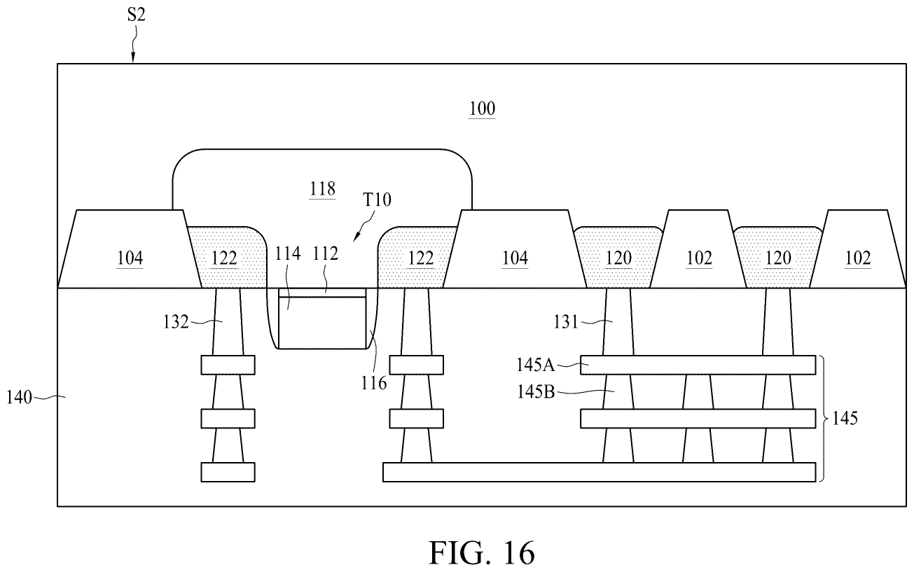

In operation 213 of FIG. 3, the substrate 100 is flipped, as shown in FIG. 16. For patterning the second surface S2 of the substrate 100 in subsequent operations, the substrate 100 is flipped so that the second surface S2 faces upward.

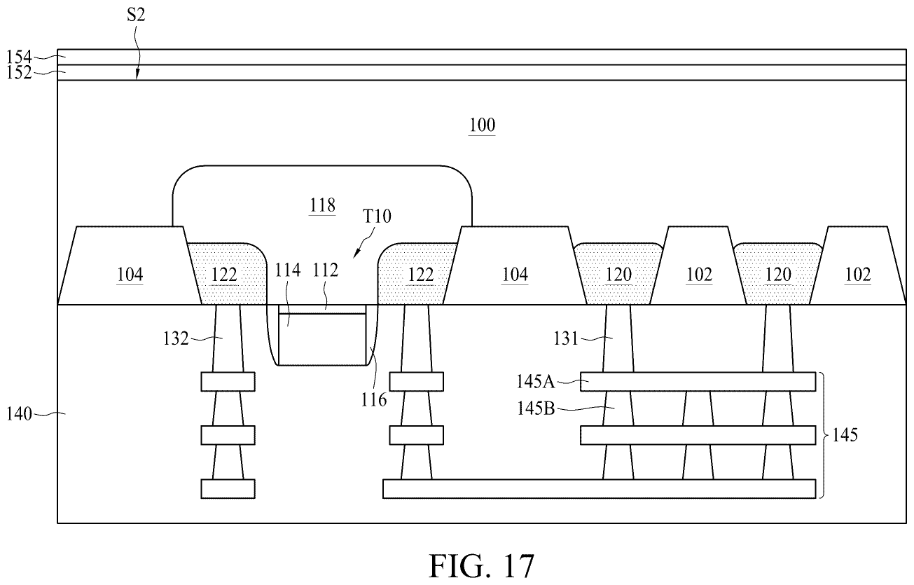

In operation 215 of FIG. 3, multiple passivation layers 152, 154 are formed on the substrate 100, as shown in FIG. 17. In some embodiments, the first passivation layer 152 is formed on the second surface S2 of the substrate 100. In some embodiments, the first passivation layer 152 is made of silicon oxide. The first passivation layer 152 may be formed by an HDP-CVD operation. The first passivation layer 152 may have a thickness between about 0.2 micrometers (μm) and about 2 μm. The forming of the silicon oxide surface on the substrate 100 may reduce the severity of narrow trenches that will be formed in subsequent operations.

In some embodiments, the second passivation layer 154 is formed on the first passivation layer 152. The second passivation layer 154 may directly contact the first passivation layer 152. In some embodiments, the second passivation layer 154 is comprised of silicon nitride or silicon oxynitride. The second passivation layer 154 may be formed by a low-pressure CVD (LPCVD) operation or a plasma-enhanced CVD (PECVD) operation. The second passivation layer 154 may have a thickness between about 2 μm and about 6 μm. The formation of the silicon nitride or silicon oxynitride surface can act as a barrier for moisture that may be present in subsequent operations.

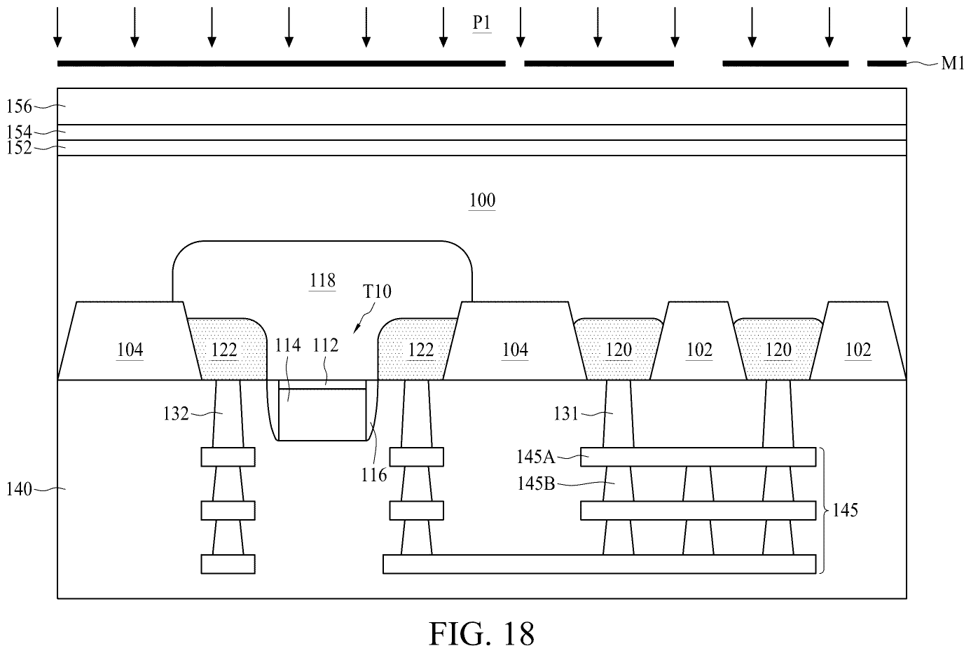

In operation 217 of FIG. 3, multiple trenches are formed penetrating the substrate 100, as shown in FIGS. 18 to 24. Referring to FIG. 18, a photoresist layer 156 is coated on the second passivation layer 154. The photoresist layer 156 is exposed to a radiation P1 such as deep ultraviolet (DUV) or extreme ultraviolet (EUV) through a photomask M1. In some embodiments, the photomask M1 is used to define trench features and through silicon via (TSV) features.

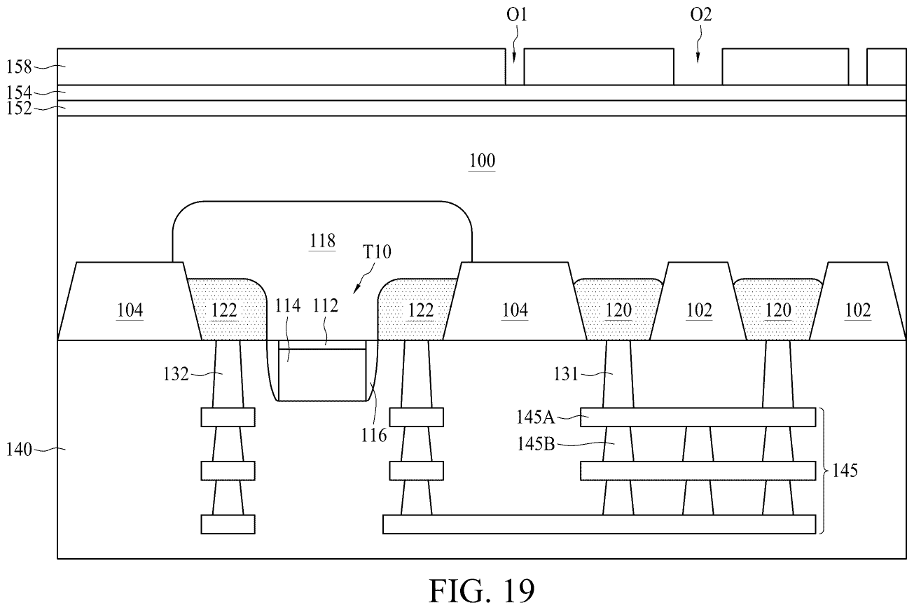

Referring to FIG. 19, after development, the exposed photoresist layer 156 may form a photoresist pattern 158 that includes multiple openings O1, O2. The openings O1, O2 expose portions of the second passivation layer 154.

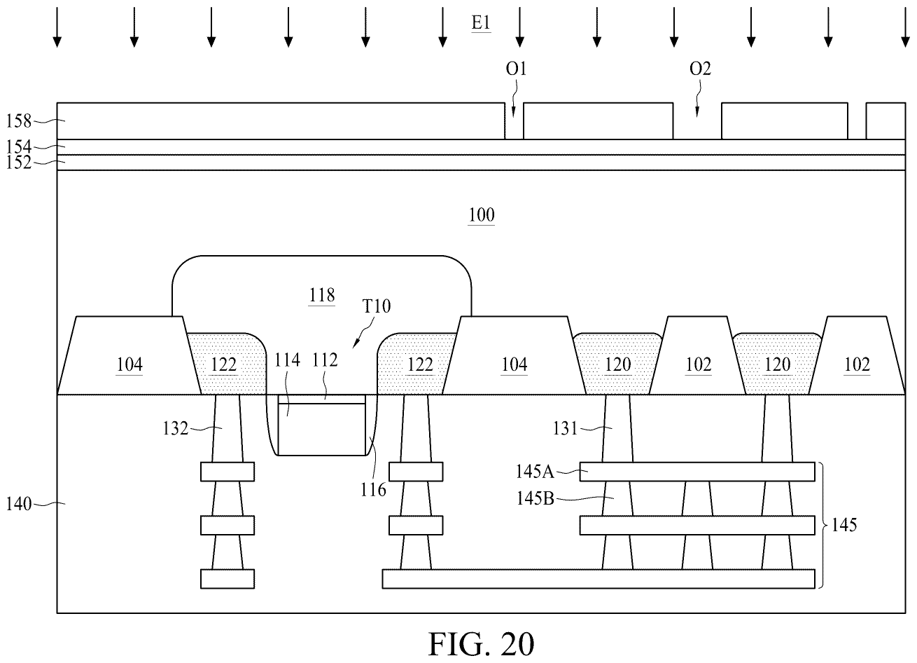

Referring to FIG. 20, a first etch operation E1 is performed on the second passivation layer 154, the first passivation layer 152 and the substrate 100 using the photoresist pattern 158 as an etching mask. The first etch operation E1 may include RIE or dry etching. In some embodiments, a chlorine (Cl₂)—based plasma is used as an etchant for the substrate 100, with a high etch rate ratio of silicon to silicon oxide. The etchant may pass through the photoresist pattern 158 via the openings O1, O2.

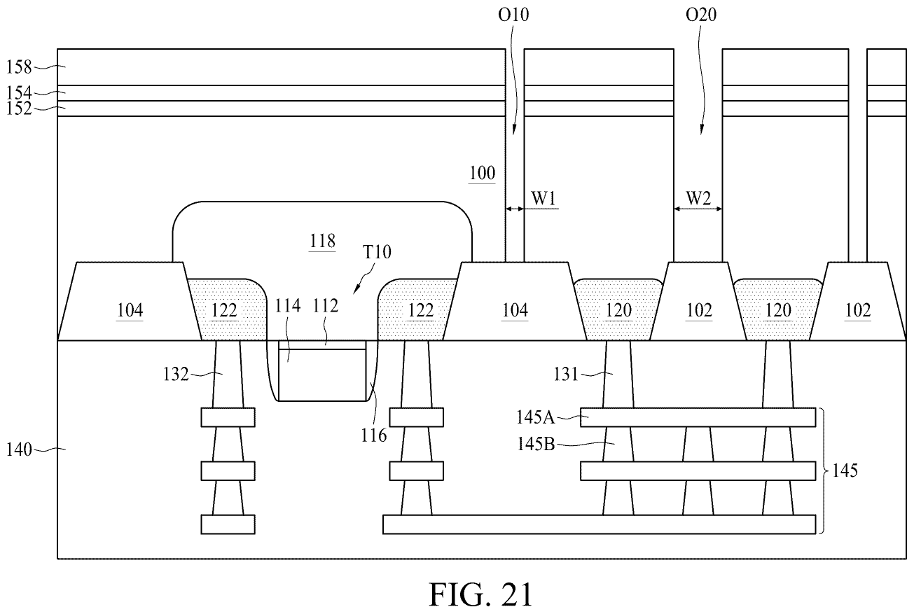

Referring to FIG. 21, the first etch operation E1 removes portions of the second passivation layer 154, the first passivation layer 152 and the substrate 100, terminating at surfaces of the isolation structures 102, 104. Multiple trenches O10 and O20 are formed penetrating the substrate 100. The trench O10 exposes a portion of the isolation structure 104, and the trench O20 exposes a portion of the isolation structure 102. In some embodiments, the trench O10 has a width W1 between about 0.3 μm and about 5 μm, about 0.8 μm, or other similar values. In some embodiments, the trench O20 has a width W2 between about 1 μm and about 10 μm, between about 3 μm and about 4 μm, or other similar values. In some embodiments, the width W2 is greater than the width W1.

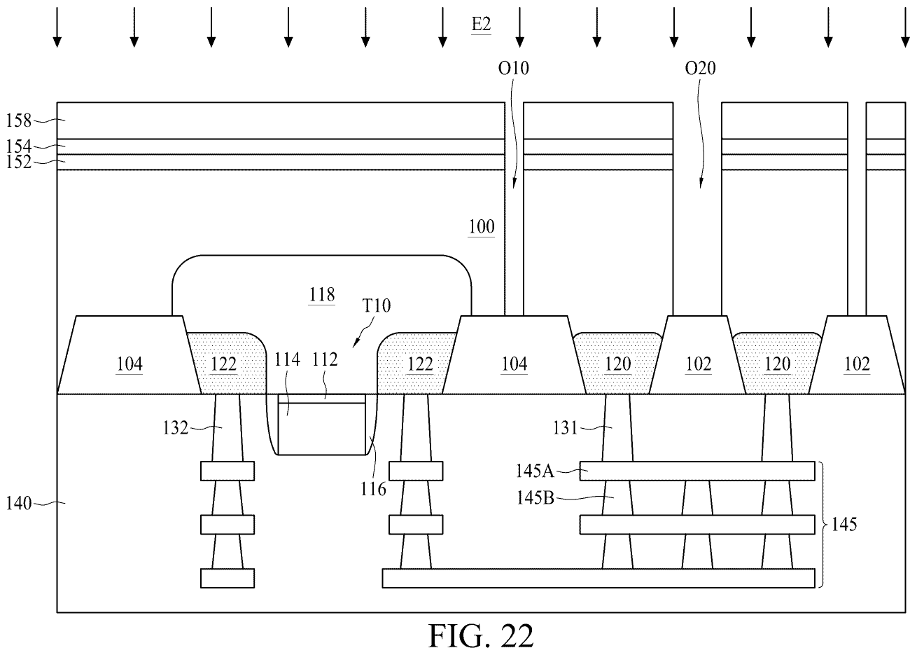

Referring to FIG. 22, a second etch operation E2 is performed on portions of the isolation structure 102 and the ILD layer 140 through the trench O20. The second etch operation E2 may include RIE or dry etching. In some embodiments, a trifluoromethane (CHF₃)-based plasma is used as an etchant in the second etch operation E2, with a high etch rate ratio of silicon oxide to silicon.

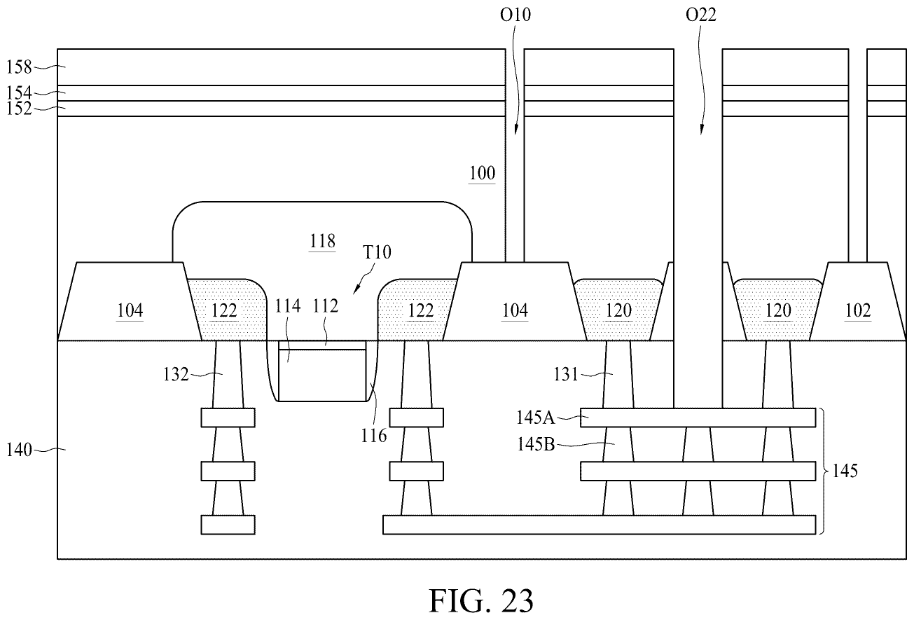

Referring to FIG. 23, the second etch operation E2 removes portions of the isolation structure 102 and the ILD layer 140 exposed by the trench O20, terminating at a surface of the conductive line 145A. The trench O20 is enlarged to form a trench O22. The trench O22 penetrates one of the isolation structures 102 and exposes a portion of the interconnect structure 145. The trench O22 may be parallel to the trench O10.

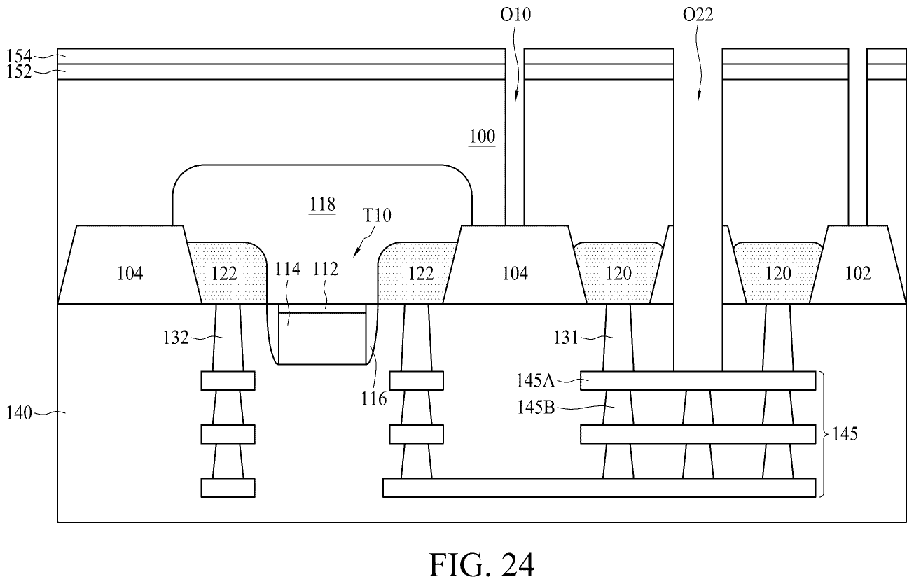

Referring to FIG. 24, after the trenches O10, O22 are formed, the photoresist pattern 158 is removed using, for example, a plasma ashing operation.

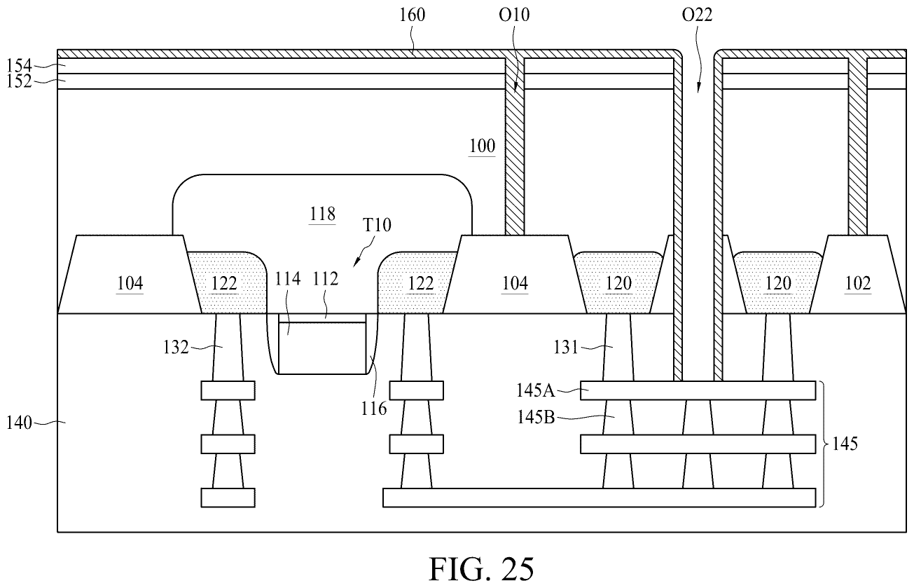

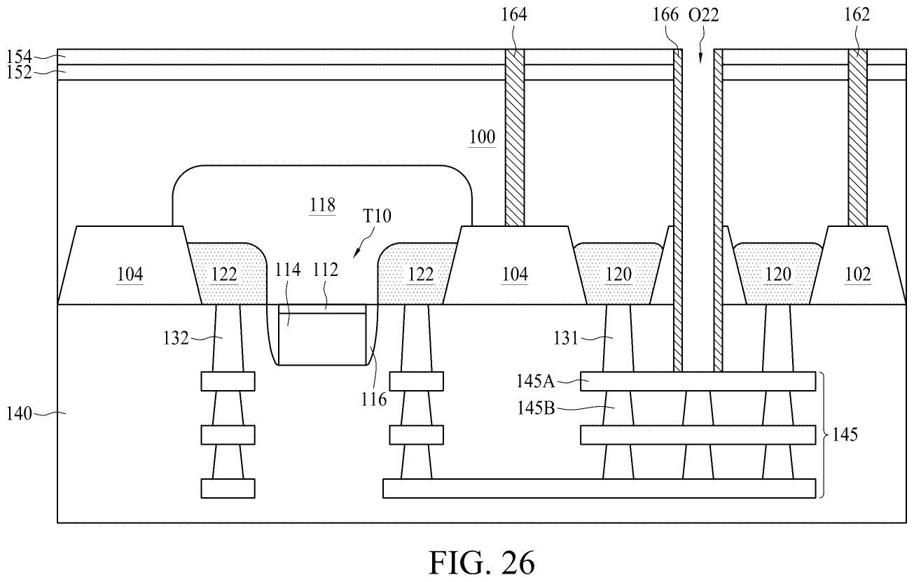

In operation 219 of FIG. 3, an insulating layer 160 is deposited in the trenches O10, O22, as shown in FIGS. 25 and 26. Referring to FIG. 25, the insulating layer 160 is formed on the second passivation layer 154 and in the trenches O10, O22. In some embodiments, the insulating layer 160 is comprised of silicon oxide and formed using an atomic layer deposition (ALD) operation. In other embodiments, the insulating layer 160 may comprise silicon nitride, silicon carbide, tetraethyl orthosilicate (TEOS), or the like. The ALD operation may be performed for an amount of time until the trenches O10 are completely filled by the insulating layer 160. Because the width W2 of the trench O22 is greater than the width W1 of the trench O10, the trench O22 is not filled by the insulating layer 160 before the trenches O10 are completely filled. A thin film of the insulating layer 160 may be conformally deposited on a sidewall of the trench O22. A portion of the conductive line 145A may still be exposed at such time.

Referring to FIG. 26, a CMP operation is used to remove the insulating layer 160 from a top surface of the second passivation layer 154. Second insulating features 162 and 164 may be formed on the isolation structures 102 and 104, respectively. The second insulating features 162, 164 may be deep trench isolation (DTI) structures. A first insulating feature 166 may be formed lining the sidewall of the trench O22. The first insulating feature 166 may contact the conductive line 145A. The first insulating feature 166 may be parallel to the second insulating feature 162 or 164.

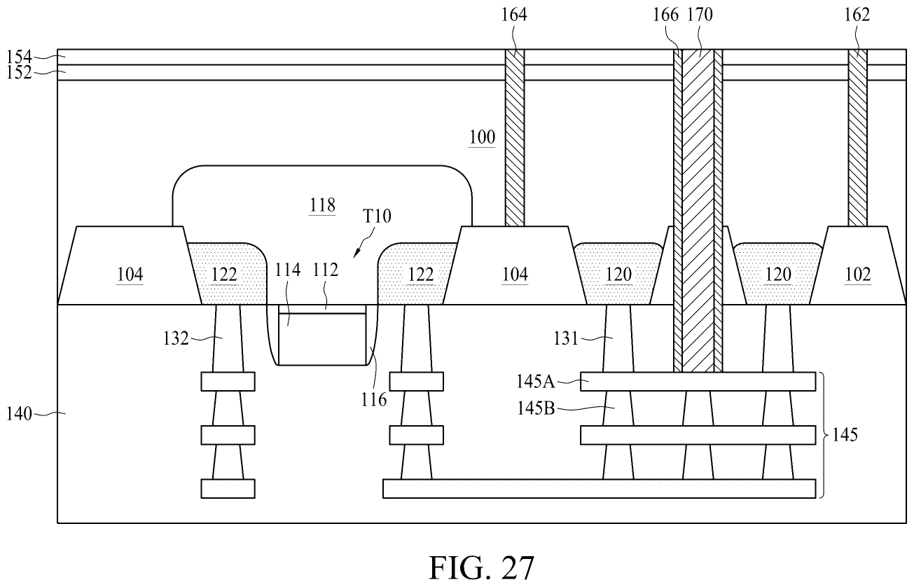

In operation 221 of FIG. 3, a conductive material is deposited in the trench O22 to form a TSV structure 170, as shown in FIG. 27. The conductive material may include W, Cu, Co, Al, Ni, Ta, Ti, Mo, Pd, Pt, Ru, Ir, Ag, Au, the like, or a combination thereof. The conductive material may be formed using sputtering, electroplating, PVD or other suitable methods. A CMP operation is used to remove any excess conductive material from the top surface of the second passivation layer 154, thereby forming the TSV structure 170. In some embodiments, the TSV structure 170 is surrounded by the first insulating feature 166. The TSV structure 170 may be electrically coupled to the interconnect structure 145 by the conductive line 145A. In some embodiments, the interconnect structure 145 over the substrate 100 is configured to electrically couple the TSV structure 170 to the doped region 120.

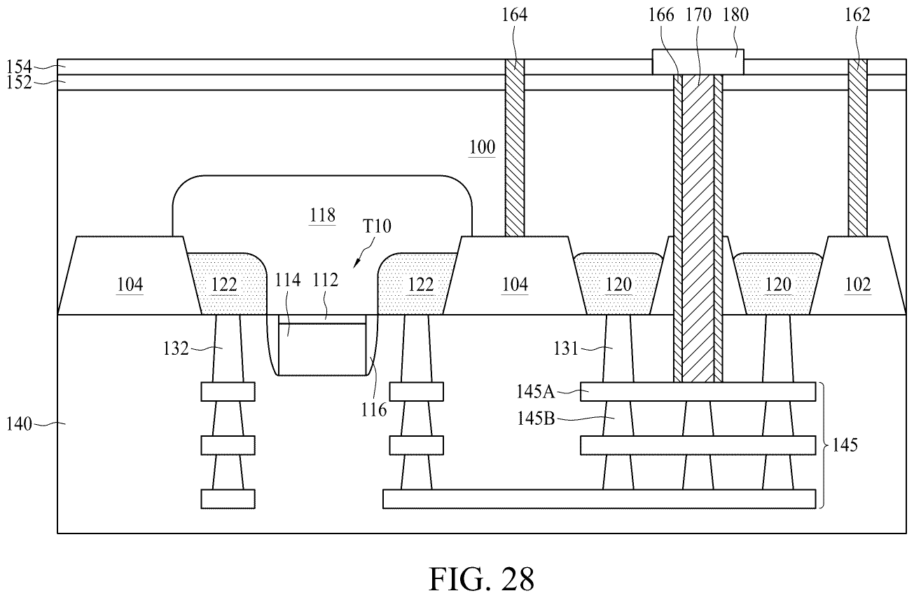

In operation 223 of FIG. 3, a conductive pad 180 is formed on the TSV structure 170, as shown in FIG. 28. Portions of the TSV structure 170 and the second passivation layer 154 may be removed to form an opening. A conductive material such as Cu or Al may be deposited in the opening to form the conductive pad 180. A bias voltage may be applied to the TSV structure 170 via the conductive pad 180.

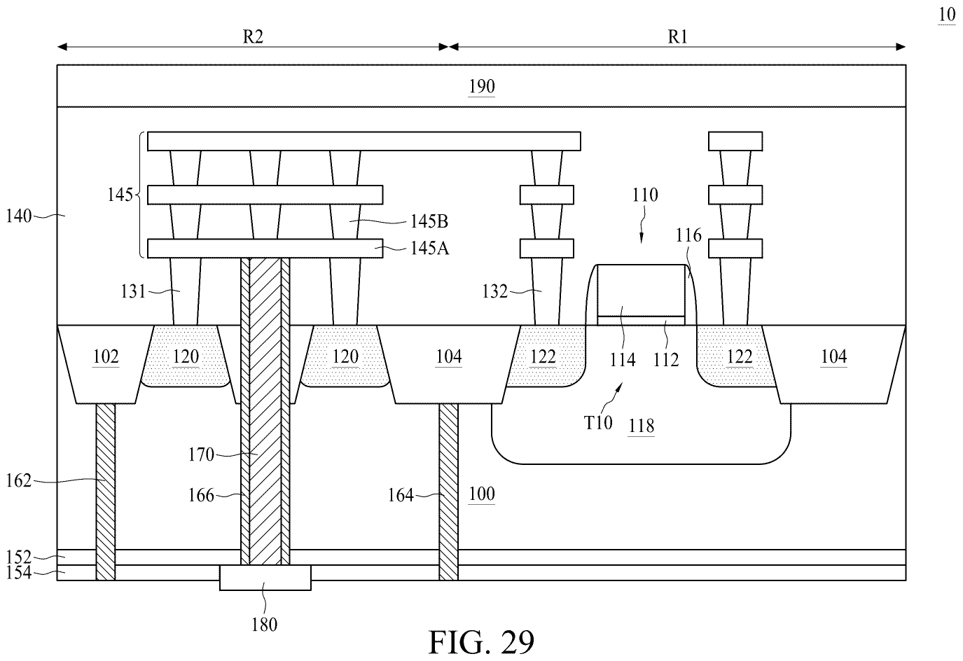

In operation 225 of FIG. 3, the substrate 100 is flipped again, as shown in FIG. 29. At this stage, the semiconductor device 10 is complete. In some embodiments, a carrier wafer 190 is disposed over the interconnect structure 145 if a wafer-on-wafer (WoW) bonding operation is subsequently performed on the semiconductor device 10. The carrier wafer 190 may be directly formed on the ILD layer 140.

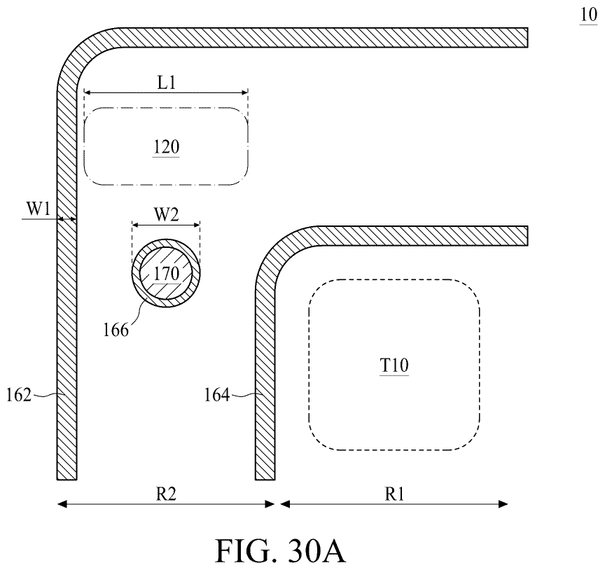

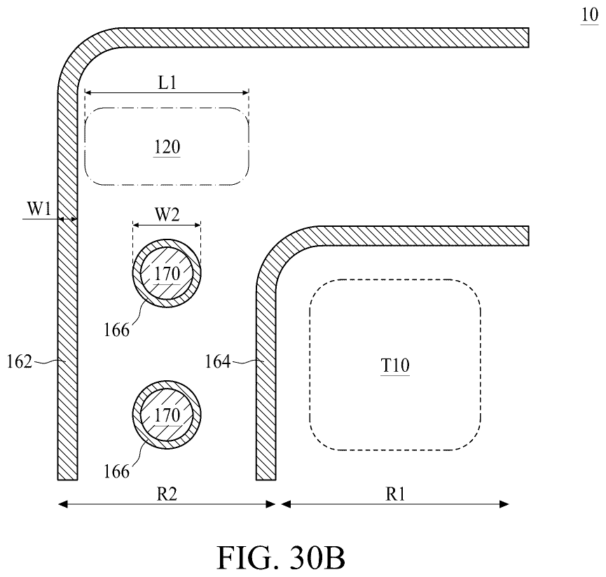

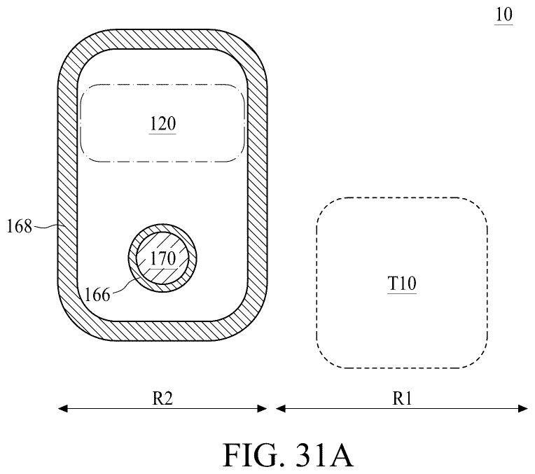

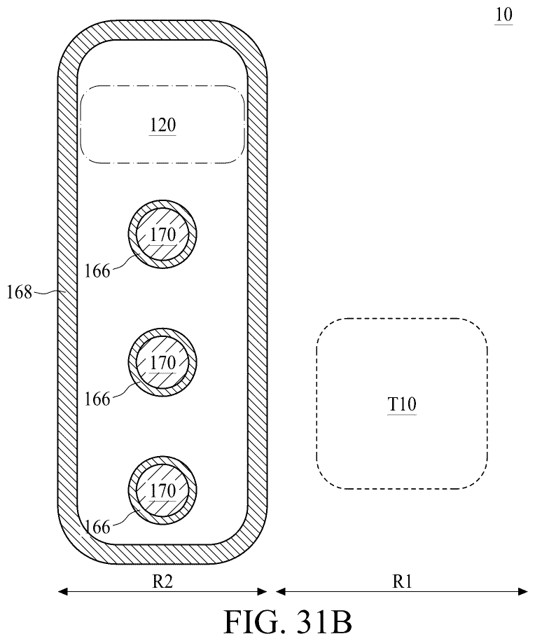

FIGS. 30A, 30B, 31A and 31B are schematic top views showing portions of the semiconductor device 10 in FIG. 29 according to various embodiments. Referring to FIGS. 30A and 30B, in some embodiments, the second insulating features 162, 164 in the top view appear as portions of ring structures. In some embodiments, one TSV structure 170 is disposed between the second insulating features 162 and 164, as shown in FIG. 30A. In some other embodiments, multiple TSV structures 170 are disposed between the second insulating features 162 and 164, as shown in FIG. 30B. In some embodiments, the second insulating feature 164 is disposed at one side of the TSV structure 170, and the second insulating feature 162 is disposed at another side of the TSV structure 170. The second insulating feature 164 separates the TSV structure(s) 170 in the peripheral area R2 from the transistor T10 in the device area R1. The ring structures of the second insulating features 162, 164 can function as a barrier layer that prevents the conductive material of the TSV structures 170, such as Cu, from diffusing to the silicon of the substrate 100 close to the device area R1. In some embodiments, the doped region 120 is disposed adjacent to at least one TSV structure 170 and between the second insulating feature 162 and the second insulating feature 164. In some embodiments, the doped region 120 has a length L1 between about 0.1 μm and about 10 μm, about 2 μm, or other similar values. In some embodiments, the doped region 120 is configured to be supplied with the same potential as the bias voltage applied to the TSV structure(s) 170. By such design, a lateral electrical field at a TSV sidewall oxide (i.e., the first insulating feature 166 that surrounds the TSV structure 170) can be significantly reduced. Since the TSV structure 170 is enclosed in the first insulating feature 166, the first insulating feature 166 can function as a barrier layer that prevents the conductive material of the TSV structure 170 from diffusing to the nearby silicon of the substrate 100. Therefore, a possible current leakage path to the silicon of the substrate 100 may be prevented. A risk of a potential drop occurring at an interface between the TSV structure 170 and the substrate 100 is decreased. In addition, since the doped region 120 is supplied with the same potential as the bias voltage applied to the TSV structure 170, the TSV sidewall oxide may not burn out due to potential equalization. As a result, even when the bias voltage is high, greater than 200 V for example, the TSV sidewall oxide may not break down.

Referring to FIG. 31A, in some other embodiments, the second insulating features 162, 164 are replaced with a single insulating feature 168 disposed at the peripheral area R2. The insulating feature 168 is similar to the second insulating feature 162 or 164, but with a difference in shape. The insulating feature 168 has a ring profile encircling the doped region 120 and the TSV structure 170 in the top view.

Referring to FIG. 31B, in some other embodiments, the insulating feature 168 encircles one doped region 120 and multiple TSV structures 170 in the top view. In some embodiments, the doped region 120 is configured to be supplied with the same potential as a bias voltage applied to one of the TSV structures 170. In some other embodiments, a bias voltage is simultaneously applied to all the TSV structures 170, and the doped region 120 is configured to be supplied with the same potential as the bias voltage applied to all the TSV structures 170.

One aspect of the present disclosure provides a semiconductor device. The semiconductor device includes a substrate including a device area and a peripheral area surrounding the device area. A via is disposed at the peripheral area and extending at least partially through the substrate. An insulating structure is disposed at the peripheral area and extending at least partially through the substrate and surrounding the via. A doped region is disposed at the peripheral area, over or in the substrate and adjacent to the via. The doped region is between the via and the insulating structure. One or more interconnects disposed within an inter-level dielectric (ILD) over the substrate and configured to electrically couple the via to the doped region.

One aspect of the present disclosure provides another semiconductor device. The semiconductor device includes a substrate. A via is disposed in the substrate. A first ring structure is disposed at one side of the via and separating the via from a transistor in the device area. A second ring structure is disposed at another side of the via. A conductive region is disposed between the first ring structure and the second ring structure. The conductive region is configured to be electrically coupled to the via.

Another aspect of the present disclosure provides a method of manufacturing a semiconductor device. The method includes: providing a substrate having a first surface and a second surface opposite to the first surface; forming an isolation structure in the substrate at the first surface; forming a doped region along the first surface, the isolation structure surrounding the doped region; forming an interconnect structure within a dielectric layer on the first surface, the interconnect structure being coupled to the doped region; removing a portion of the substrate from the second surface to form a first trench that exposes a portion of the isolation structure, and removing another portion of the substrate from the second surface to form a second trench that exposes a portion of the interconnect structure; filling the first trench with a dielectric material and disposing the dielectric material conformally on a sidewall of the second trench; and filling the second trench with a conductive material, wherein the conductive material is surrounded by the dielectric material.

The foregoing outlines structures of several embodiments so that those skilled in the art may better understand aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

The invention claimed is:

1. A semiconductor device, comprising:
a substrate comprising a device area and a peripheral area surrounding the device area;
a via disposed at the peripheral area and extending at least partially through the substrate;
an insulating structure disposed at the peripheral area and extending at least partially through the substrate and laterally surrounding the via in a cross-sectional view;
a doped region disposed at the peripheral area, over or in the substrate and adjacent to the via, wherein the doped region is between the via and the insulating structure; and
one or more interconnects disposed within an inter-level dielectric (ILD) over the substrate and configured to electrically couple the via to the doped region.

2. The semiconductor device of claim 1, wherein the insulating structure surrounds the doped region.

3. The semiconductor device of claim 1, wherein the insulating structure has a ring profile encircling the via and the doped region from a top view.

4. The semiconductor device of claim 1, further comprising a barrier layer between the substrate and the via, wherein the barrier layer surrounds the via.

5. The semiconductor device of claim 1, further comprising a transistor disposed in the device area, wherein the insulating structure is disposed between the transistor and the via.

6. The semiconductor device of claim 5, further comprising:
a dielectric layer, disposed over the substrate; and
an interconnect structure, disposed in the dielectric layer and over the via and the device area, wherein
one end of the interconnect structure is electrically coupled to the doped region, and another end of the interconnect structure is electrically coupled to the transistor.

7. The semiconductor device of claim 6, wherein the via is electrically coupled to the interconnect structure.

8. A semiconductor device, comprising:
a substrate defined with a device area and a peripheral area;
a via disposed in the substrate;
a first ring structure disposed at one side of the via and separating the via from a transistor in the device area;
a second ring structure disposed at another side of the via; and
a conductive region disposed between the first ring structure and the second ring structure, wherein the conductive region is configured to be electrically coupled to the via.

9. The semiconductor device of claim 8, wherein the first ring structure and the second ring structure are trench isolation structures.

10. The semiconductor device of claim 8, wherein the conductive region between the first ring structure and the second ring structure is proximal to the via.

11. The semiconductor device of claim 8, further comprising an interconnect structure disposed over the substrate and configured to electrically couple the via to the conductive region.

12. The semiconductor device of claim 8, wherein the via, the first ring structure and the second ring structure are disposed at the peripheral area, and the transistor is disposed at the device area.

13. The semiconductor device of claim 8, wherein the via includes a conductive material surrounded by a dielectric that isolates the conductive material from the substrate.

14-20. (canceled)

21. A semiconductor device, comprising:
a substrate having a first side and a second side opposing the first side, wherein the substrate comprises a device region and a peripheral region laterally adjacent to the device region;
a via extending between the first side of the substrate and the second side of the substrate within the peripheral region;
one or more insulating features disposed on opposing sides of the via and laterally between the via and the device region, wherein the one or more insulating features are arranged along the second side of the substrate and are laterally separated from opposing sidewalls of the via by the substrate; and
a doped region disposed within the peripheral region between the via and the one or more insulating features.

22. The semiconductor device of claim 21, wherein the one or more insulating features wrap around both the via and the doped region in a closed loop, as viewed in a top-view of the one or more insulating features.

23. The semiconductor device of claim 22, wherein an entirety of the closed loop is arranged along a single side of the device region in the top-view.

24. The semiconductor device of claim 21, wherein the one or more insulating features comprise a first segment that extends past the via along a first direction and a second segment that extends past the via along a second direcetion that is perpendicular to the first direction in a top-view.

25. The semiconductor device of claim 21, wherein the via has a larger continuous lateral width than the one or more insulating features.

26. The semiconductor device of claim 21, further comprising:
one or more first isolation structures arranged along the first side of the substrate, wherein the one or more insulating features extend between the second side of the substrate and the one or more first isolation structures; and
a second isolation structure arranged along the first side of the substrate, wherein the via extends vertically through the second isolation structure to within an inter-level dielectric (ILD) structure arranged on the first side of the substrate.

27. The semiconductor device of claim 26, wherein the doped region continuously extends from the one or more first isolation structures to the second isolation structure.
